(19) United States
(12) Patent Application Publication
(10) Pub. No.: US 2026/0082601 A1
(43) Pub. Date: Mar. 19, 2026

(54) STACKED PIN DIODE AND METHOD OF MAKING SAME

(71) Applicant: TAIWAN SEMICONDUCTOR MANUFACTURING COMPANY, LTD., Hsinchu (TW)

(72) Inventors: Yu-Hung YEH, Hsinchu (TW); Jui-Chien HUANG, Hsinchu (TW); Wun-Jie LIN, Hsinchu (TW)

(21) Appl. No.: 19/041,443

(22) Filed: Jan. 30, 2025

Related U.S. Application Data
(60) Provisional application No. 63/695,622, filed on Sep. 17, 2024.

(51) Int. Cl. H10D 8/50; H10D 62/832; H10D 64/01; H10D 84/00

(52) U.S. Cl. CPC H10D 8/50; H10D 62/832; H10D 64/017; H10D 84/221

(57) ABSTRACT

A diode structure includes a first stack of semiconductor layers, wherein the first stack of semiconductor layers includes a plurality of first semiconductor layers arranged in an alternating arrangement with a plurality of second semiconductor layers. The diode structure further includes a second stack of semiconductor layers, wherein the second stack of semiconductor layers includes a plurality of third semiconductor layers arranged in an alternating arrangement with a plurality of fourth semiconductor layers. The diode structure further includes a fifth semiconductor layer between the first stack of semiconductor layers and the second stack of semiconductor layers, wherein a composition of the fifth semiconductor layer is different from each of the plurality of first, second, third and fourth semiconductor layers. The diode structure further includes an n-type doped region in the first stack of semiconductor layers; and a p-type doped region in the second stack of semiconductor layers.

### PRIORITY CLAIM AND CROSS-REFERENCE

This application claims priority to U.S. Provisional Application No. 63/695,622 filed Sep. 17, 2024, the entire contents of which are hereby incorporated by reference.

### BACKGROUND

An integrated circuit (IC) includes a number of IC devices that are manufactured in accordance with one or more IC layout diagrams. IC devices sometimes include complementary field effect transistor (CFET) devices. A CFET device generally has an upper FET overlying a lower FET in a stacked configuration. Both the upper FET and the lower FET in a CFET device are positioned above the conductive lines in a back-side conductive layer but below the conductive lines in a front-side conductive layer. In addition to active devices, such as CFET devices, the IC devices include passive devices, such as diodes, resistors, capacitors or inductors, in some instances. In some approaches that utilize fin field effect transistor (FinFET) or nanosheet production processes, diodes are formed that share a doped well. The amount of space in the IC occupied by such diodes is significant because both p-type and n-type devices are formed in the shared well.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a stacked PIN diode in accordance with some embodiments.

FIG. 2 is a flowchart of a method of making a stacked PIN diode in accordance with some embodiments.

FIGS. 3A-3C are cross-sectional views of a stacked PIN diode at various stages of manufacture in accordance with some embodiments.

FIG. 4 is a flowchart of a method of making a stacked PIN diode simultaneously with a complementary field effect transistor (CFET) in accordance with some embodiments.

FIGS. 5A-5K are cross-sectional views of a stacked PIN diode manufactured simultaneously with a CFET in accordance with some embodiments.

FIGS. 6A-6K are cross-sectional views of a CFET manufactured simultaneously with a stacked PIN diode in accordance with some embodiments.

FIG. 7 is a schematic diagram of an integrated circuit (IC) including a stacked PIN diode in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As technology advances, there is increased pressure to reduce the size of integrated circuit (IC) devices. A promising development in active devices is a complementary field effect transistor (CFET). The CFET stacks elements of the transistor in a vertical fashion, which reduces an overall size of the device in comparison with other approaches, such as fin field effect transistor (FinFET) or nanosheet transistors. While the CFET process offers improvements for the size of transistors, passive devices, such as diodes, also occupy a significant amount of space in an IC due to the size of the passive devices. Diodes used in approaches such as FinFET or nanosheet transistors, include both a p-type device and an n-type device. The p-type device and n-type device share a common well to form a well diode structure. Due to the inclusion of two types of devices, i.e., p-type and n-type, a size of the diode within the IC is relatively large. In order to help to reduce the size of diodes in the IC, a stacked PIN diode that is compatible with CFET manufacturing is described in this disclosure.

The stacked PIN diode includes the p-type device separated from the n-type device in a vertical direction. This vertical arrangement helps to reduce a footprint of the stacked PIN diode in an IC in comparison with diodes that horizontally separate the p-type device and n-type device. The stacked PIN diode is also compatible with a manufacturing process used to produce CFET devices. In some embodiments, the stacked PIN diode is able to be manufactured simultaneously with one or more CFET devices in order to improve manufacturing efficiency and throughput. The manufacturing process for the stacked PIN diode shares a number of operations with the manufacturing process of a CFET device. However, since the structure of the stacked PIN diode is less complex than the structure of the CFET device, the stacked PIN diode is shield, e.g., using a photoresist, during some operations used to manufacture the CFET device. The ability to simultaneously manufacture the stacked PIN diode with the CFET device enhances the integration of the stacked PIN diode into the production of future IC devices.

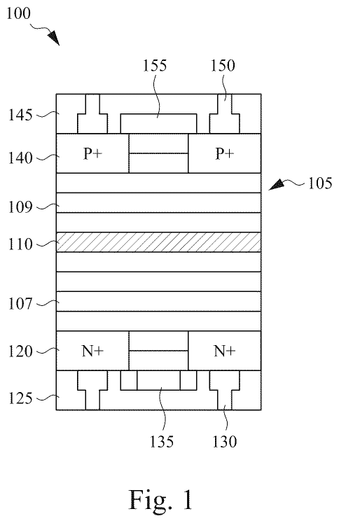

FIG. 1 is a cross-sectional view of a stacked PIN diode 100 in accordance with some embodiments. The staked PIN diode 100 includes a stack 105 of alternating semiconductor layers. The stack 105 of alternating semiconductor layers includes layers 107 of a first semiconductor material arranged in an alternating fashion with layers 109 of a second semiconductor material. The second semiconductor material includes a different composition from the first semiconductor layer. The stack 105 of alternating semiconductor layers further includes a semiconductor layer 110 which includes a layer of semiconductor materials and has a different composition from each of the first semiconductor material and the second semiconductor material.

The stacked PIN diode 100 further includes p-type wells 120 in the stack 105 of alternating semiconductor layers. The p-type wells 120 are separated from one another in a horizontal direction. A first dielectric layer 125 extends across a surface of the stack 105 of alternating semiconductor layers. The first dielectric layer 125 overlaps each of the p-type wells 120. Contact structures 130 extend through the first dielectric layer 125 in a vertical direction. Each of the contact structures 130 is electrically connected to a corresponding p-type well 120. Although not shown for the sake of clarity of the drawings, one of ordinary skill in the art would understand that the contact structures 130 are able to electrically connect to an interconnect structure in order to propagate signals, power, or ground voltage to the p-type wells 120. A mask material 135 is also in the first dielectric layer 125. The mask material 135 is usable to determine the location of each of the p-type wells 120 in the stack 105 of alternating semiconductor layers. In some embodiments, the mask material 135 is omitted from the stacked PIN diode 100.

The stacked PIN diode 100 further includes n-type wells 140 in the stack 105 of alternating semiconductor layers. The n-type wells 140 are separated from one another in the horizontal direction. A second dielectric layer 145 extends across a surface of the stack 105 of alternating semiconductor layers. The second dielectric layer 145 overlaps each of the n-type wells 140. Contact structures 150 extend through the second dielectric layer 145 in the vertical direction. Each of the contact structures 150 is electrically connected to a corresponding n-type well 140. Although not shown for the sake of clarity of the drawings, one of ordinary skill in the art would understand that the contact structures 150 are able to electrically connect to an interconnect structure in order to propagate signals, power, or ground voltage to the n-type wells 140. A mask material 155 is also in the second dielectric layer 145. The mask material 155 is usable to determine the location of each of the n-type wells 140 in the stack 105 of alternating semiconductor layers. In some embodiments, the mask material 155 is omitted from the stacked PIN diode 100.

The stack 105 of alternating semiconductor layers includes first semiconductor layers 107 and second semiconductor layers 109 arranged alternatingly. One of ordinary skill in the art would understand that the current application is not limited to the number of layers in the stack 105 of alternating semiconductor layers indicated in FIG. 1. The number of layers in the stack 105 of alternating semiconductor layers is determined based on a combination of factors, such as sufficient spacing between the p-type wells 120 and the n-type well 140 to reduce a risk of shorting within the stacked PIN diode 100, as well as a size of the stacked PIN diode 100. Further, one of ordinary skill would understand that an odd number or even number of layers in the stack 105 of alternating semiconductor layers is within the scope of this description. Each layer of the stack 105 of alternating semiconductor layers is grown by a process such as Vapor Phase Epitaxy (VPE) or Molecular Beam Epitaxy (MBE), deposited by a process such as a Chemical Vapor Deposition (CVD) process, an Atomic Layer deposition (ALD) process, or the like. In some embodiments, each of the layers in the stack 105 of alternating semiconductor layers is formed using a same process. In some embodiments, at least one layer of the stack 105 of alternating semiconductor layers is formed using a different process from at least one other layer of the stack 105 of alternating semiconductor layers. In some embodiments, each of the first semiconductor layers 107 is formed using a first process and each of the second semiconductor layers 109 is formed using a second process, different from the first process. In some embodiments, the semiconductor layer 110 is formed using a different process from that used to form at least one of the first semiconductor layers 107 or the second semiconductor layers 109.

The first semiconductor layers 107 include silicon. In some embodiments, the first semiconductor layers 107 include pure silicon, e.g., a silicon atomic percentage of 95% or more. In some embodiments, the first semiconductor layers 107 include silicon with a low concentration of germanium. In some embodiments, an atomic percentage of germanium in the first semiconductor layers 107 is less than about 5%.

The second semiconductor layers 109 include silicon germanium. The germanium concentration in the second semiconductor layers 109 is greater than the germanium concentration in the first semiconductor layers 107. In some embodiments, the atomic percentage of germanium in the second semiconductor layers 109 ranges from about 10% to about 50%.

The semiconductor layer 110 helps with gate isolation in CFET devices. The inclusion of semiconductor layer 110 in the stacked PIN diode 100 helps to integrating the stacked PIN diode 100 into a manufacturing process with CFET devices. In some embodiments where the stacked PIN diode 100 is formed independently from CFET devices, the stacked PIN diode 100 does not include the semiconductor layer 110. The semiconductor layer 110 is included in a central portion of the stack 105 of alternating semiconductor layers. In some embodiments, the semiconductor layer 110 is a center layer of the stack 105 of alternating semiconductor layers. In some embodiments, the semiconductor layer 110 is not the center layer of the stack 105 of alternating semiconductor layers. The semiconductor layer 110 replaces one of the second semiconductor layers 109 in the alternating sequence between the first semiconductor layers 107 and the second semiconductor layers 109. The semiconductor layer 110 includes germanium. In some embodiments, the semiconductor layer 110 further includes silicon. In some embodiments, the semiconductor layer 110 further includes dopants, such as n-type dopants or p-type dopants. The semiconductor layer 110 has a higher germanium concentration than the second semiconductor layers 109. In some embodiments, the semiconductor layer 110 includes pure germanium, e.g., an atomic percentage of germanium of at least 95%. In some embodiments, the semiconductor layer 110 includes silicon germanium. In some embodiments, an atomic percentage of germanium in the semiconductor layer 110 ranges from about 60% to about 90%.

The p-type wells 120 are formed in the stack 105 of alternating semiconductor layers. In some embodiments semiconductor material is doped, for example, using an implant process to form the stacked PIN diode 100. By way of example and not limitation, the stack 105 of alternating semiconductor layers is doped during the process of forming source/drain regions in CFET devices. In some embodiments, a sacrificial hard mask layer is formed on a surface of the stack 105 of alternating semiconductor layers to modulate the implant depth and thus the thickness of a p-type wells 120. For example, the depth of the resulting p-type wells 120 is inversely proportional or related to the thickness of the sacrificial hard mask layer. In some embodiments, the hard mask layer is, for example, a stacked layer of silicon oxide and silicon nitride. In some embodiments, the depth of p-type wells 120 is modulated through implant process conditions, e.g., the implant energy. In some embodiments, a dopant dose for forming the p-type wells 120 ranges from 1×10¹² cm⁻² to about 5×10¹⁶ cm⁻² and a dopant species includes boron, indium, gallium, or another suitable p-type dopant.

In some embodiments, an ion implantation process for forming the p-type wells 120 uses an ion beam energy in a range, for example, from approximately 1 KeV to approximately 15 KeV. The dopants are implanted the stack 105 of alternating semiconductor layers, for example, in a range from about 5 nm to about 20 nm. In some embodiments, a dopant concentration of the p-type wells 120 ranges, for example, from about 1×10¹⁹ cm⁻³ to about 1×10²¹ cm⁻³. In some embodiments, the implantation process is followed by an annealing process. In some embodiments, implantation of dopants into the stack 105 of alternating semiconductor layers is not followed with a post-anneal.

The first dielectric layer 125 extends along the surface of the stack 105 of alternating semiconductor layers. The first dielectric layer 125 is usable to provide a contact layer for connecting an interconnect structure on a first side of the stack PIN diode 100 to the p-type wells 120. In some embodiments, the first dielectric layer 125 includes silicon oxide, silicon carbide, silicon oxynitride, silicon oxycarbide, combinations thereof, or other suitable dielectric materials. In some embodiments, the first dielectric layer 125 is formed using CVD, PECVD, ALD, or another suitable deposition process.

The contact structures 130 extend through the first dielectric layer 125 to facilitate electrical connection between an interconnect structure and the p-type wells 120. While stacked PIN diode 100 is shown in FIG. 1 has having a stepped profile for the contact structures 130, one of ordinary skill in the art would recognize that the contact structures 130 are not limited to this shape. In some embodiments, the contact structures 130 have a tapered profile or substantially parallel sidewalls. In some embodiments, the contact structures include copper, aluminum, tungsten, cobalt, alloys thereof, or other suitable conductive materials. In some embodiments, the contact structures are formed using physical vapor deposition (PVD), CVD, ALD, or other suitable deposition processes. In some embodiments, the contact structures 130 include diffusion barriers to help prevent diffusion of the conductive material into the first dielectric layer 125.

The mask material 135 is usable to determine the locations of the p-type wells 120 in the stack 105 of alternating semiconductor layers. The mask material 135 is deposited along the surface of the stack 105 of alternating semiconductor layers and patterned to define openings exposing the stack 105 of alternating semiconductor layers. The implantation process for forming the p-type wells 120 is performed through the openings to implant the p-type dopants into the stack 105 of alternating semiconductor layers. In some embodiments, the mask material 135 includes a photoresist, silicon nitride, silicon oxynitride, or other suitable materials. In some embodiments, the mask material 135 is a single layer. In some embodiments, the mask material is multiple layers. In some embodiments, the mask material 135 includes a hard mask underlying, e.g., the photoresist. In some embodiments, the hard mask includes titanium nitride, cobalt nitride, silicon nitride or another suitable material.

In some embodiments, the mask material 135 is omitted from the stacked PIN diode 100. For example, following the implantation of the p-type wells 120 into the stack 105 of alternating semiconductor layers, the mask material 135 is removed prior to forming the first dielectric layer 125. In some embodiments where the mask material 135 is removed, the first dielectric layer 125 contacts an entirety of the surface of the stack 105 of alternating semiconductor layers between the p-type wells 120. In some embodiments, the mask material 135 is removed using etching, ashing, or other suitable removal process.

The n-type wells 140 are formed in the stack 105 of alternating semiconductor layers. The n-type wells 140 are on the opposite side of the p-type wells 120 in the stack 105 of alternating semiconductor layers in vertical direction. In some embodiments semiconductor material is doped, for example, using an implant process to form the stacked PIN diode 100. By way of example and not limitation, the stack 105 of alternating semiconductor layers is doped during the process of forming source/drain regions in CFET devices. In some embodiments, a sacrificial hard mask layer is formed on a surface of the stack 105 of alternating semiconductor layers to modulate the implant depth and thus the thickness of a n-type wells 140. For example, the depth of the resulting n-type wells 140 is inversely proportional or related to the thickness of the sacrificial hard mask layer. In some embodiments, the hard mask layer is, for example, a stacked layer of silicon oxide and silicon nitride. In some embodiments, the depth of n-type wells 140 is modulated through implant process conditions, e.g., the implant energy. In some embodiments, a dopant dose for forming the n-type wells 140 ranges from 1×10¹² cm⁻² to about 5×10¹⁶ cm⁻² and a dopant species includes phosphorous, arsenic, antimony, or another suitable n-type dopant. In some embodiments, the n-type wells 140 have a same depth as the p-type wells 120. In some embodiments, the n-type wells 140 have a different depth from the p-type wells 120.

In some embodiments, an ion implantation process for forming the n-type wells 120 uses an ion beam energy in a range, for example, from approximately 1 KeV to approximately 15 KeV. The dopants are implanted the stack 105 of alternating semiconductor layers, for example, in a range from about 5 nm to about 20 nm. In some embodiments, a dopant concentration of the n-type wells 140 ranges, for example, from about 1×10¹⁹ cm⁻³ to about 1×10²¹ cm⁻³. In some embodiments, the n-type wells 140 have a same dopant concentration as the p-type wells 120. In some embodiments, the n-type wells 140 have a different dopant concentration from the p-type wells 120. In some embodiments, the implantation process is followed by an annealing process. In some embodiments, implantation of dopants into the stack 105 of alternating semiconductor layers is not followed with a post-anneal.

The second dielectric layer 145 extends along the surface of the stack 105 of alternating semiconductor layers. The second dielectric layer 145 is usable to provide a contact layer for connecting an interconnect structure on a second side of the stack PIN diode 100 to the n-type wells 140. In some embodiments, the second dielectric layer 145 includes silicon oxide, silicon carbide, silicon oxynitride, silicon oxycarbide, combinations thereof, or other suitable dielectric materials. In some embodiments, the second dielectric layer 145 is formed using CVD, PECVD, ALD, or another suitable deposition process. In some embodiments, the second dielectric layer 145 includes a same material as the first dielectric layer 125. In some embodiments, the second dielectric layer 145 includes a different material from the first dielectric layer 125.

The contact structures 150 extend through the second dielectric layer 145 to facilitate electrical connection between an interconnect structure and the n-type wells 140. While stacked PIN diode 100 is shown in FIG. 1 has having a stepped profile for the contact structures 150, one of ordinary skill in the art would recognize that the contact structures 150 are not limited to this shape. In some embodiments, the contact structures 150 have a tapered profile or substantially parallel sidewalls. In some embodiments, the contact structures 150 have a similar shape as the contact structures 130. In some embodiments, the contact structures 150 have a different shape from the contact structures 130. In some embodiments, the contact structures include copper, aluminum, tungsten, cobalt, alloys thereof, or other suitable conductive materials. In some embodiments, the contact structures are formed using physical vapor deposition (PVD), CVD, ALD, or other suitable deposition processes. In some embodiments, the contact structures 150 have a same material as the contact structures 130. In some embodiments, the contact structures 150 have a different material from the contact structures 130. In some embodiments, the contact structures 150 include diffusion barriers to help prevent diffusion of the conductive material into the second dielectric layer 145.

The mask material 155 is usable to determine the locations of the n-type wells 140 in the stack 105 of alternating semiconductor layers. The mask material 155 is deposited along the surface of the stack 105 of alternating semiconductor layers and patterned to define openings exposing the stack 105 of alternating semiconductor layers. The implantation process for forming the n-type wells 140 is performed through the openings to implant the n-type dopants into the stack 105 of alternating semiconductor layers. In some embodiments, the mask material 155 includes a photoresist, silicon nitride, silicon oxynitride, or other suitable materials. In some embodiments, the mask material 155 is a single layer. In some embodiments, the mask material is multiple layers. In some embodiments, the mask material 155 includes a hard mask underlying, e.g., the photoresist. In some embodiments, the hard mask includes titanium nitride, cobalt nitride, silicon nitride or another suitable material. In some embodiments, the mask material 155 includes a dummy gate structures. In some embodiments, the dummy gate structure includes polysilicon. In some embodiments, the dummy gate structures further include gate spacers along sidewalls of a dummy gate electrode. In some embodiments, the mask material 155 has a same structure and material as the mask material 135. In some embodiments, the mask material 155 has a different structure or material from the mask material 135.

In some embodiments, the mask material 155 is omitted from the stacked PIN diode 100. For example, following the implantation of the n-type wells 140 into the stack 105 of alternating semiconductor layers, the mask material 155 is removed prior to forming the second dielectric layer 145. In some embodiments where the mask material 155 is removed, the second dielectric layer 145 contacts an entirety of the surface of the stack 105 of alternating semiconductor layers between the n-type wells 140. In some embodiments, the mask material 155 is removed using etching, ashing, or other suitable removal processes.

In comparison with other diodes, the stack PIN diode 100 uses vertical separation between the p-type wells 120 and the n-type wells 140 in order to reduce a size of the diode in an IC. The stacked PIN diode 100 is also able to be integrated into a CFET manufacturing process in order to improve production efficiency in comparison with other approaches.

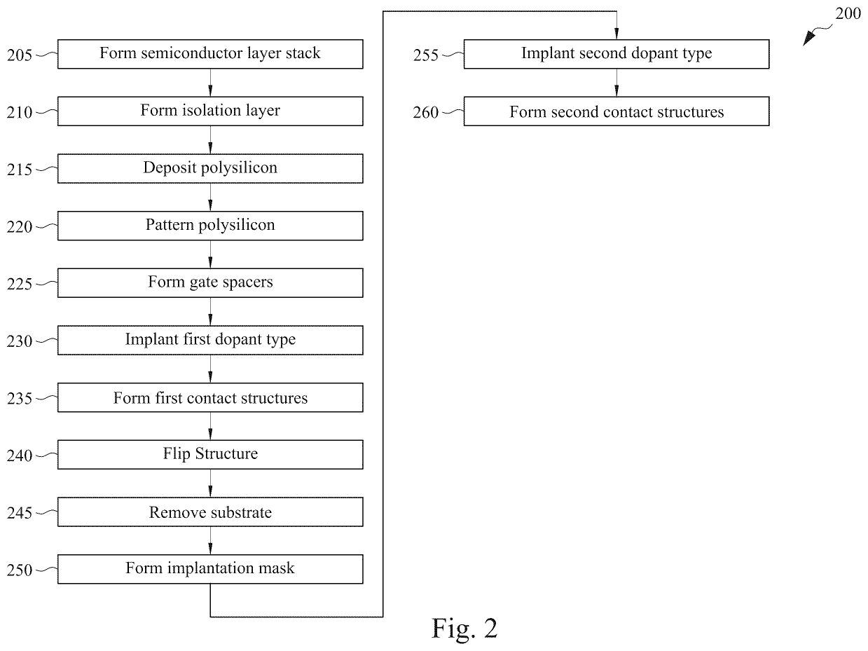

FIG. 2 is a flowchart of a method 200 of making a stacked PIN diode in accordance with some embodiments. In some embodiments, the method 200 is usable to form the stacked PIN diode 100 (FIG. 1). In some embodiments, the method 200 is usable to from a diode other than the stacked PIN diode 100 (FIG. 1). In comparison with other approaches, the method 200 is usable to form a diode having n-type wells separated from p-type wells in a vertical direction in order to reduce an amount of space that the diode occupies in the IC. This helps to facilitate further reductions in size of IC devices.

In operation 205, a semiconductor layer stack is formed on a substrate. Forming the semiconductor layer stack includes forming alternating layers of semiconductor material. Each layer of the semiconductor layer stack has a different composition from each adjacent layer within the semiconductor layer stack. In some embodiments, each layer of the semiconductor layer stack is grown by a process such as VPE or MBE, deposited by a process such as CVD process, an ALD process, or the like. In some embodiments, each of the layers in the semiconductor layer stack is formed using a same process. In some embodiments, at least one layer of the semiconductor layer stack is formed using a different process from at least one other layer of semiconductor layer stack. In some embodiments, each layer of the semiconductor layer stack has a first composition is formed using a first process and each layer of the semiconductor layer stack having a second composition is formed using a second process, different from the first process.

The first composition includes silicon. In some embodiments, the first composition includes pure silicon, e.g., a silicon atomic percentage of 95% or more. In some embodiments, the first composition includes silicon with a low concentration of germanium. In some embodiments, an atomic percentage of germanium in the first composition is less than about 5%. The second composition silicon germanium. The germanium concentration in the second composition is greater than the germanium concentration in the first composition. In some embodiments, the atomic percentage of germanium in the second composition ranges from about 10% to about 50%. In some embodiments, the operation 205 forms the stack 105 of alternating semiconductor layers 105 (FIG. 1).

In operation 210, a semiconductor layer is formed. In some embodiments, the operation 210 is integrated into the operation 205. For example, in some embodiments, the operation 210 is performed following a first performance of the operation 205 and then a second performance of the operation 205 is performed following the operation 210. In some embodiments, the operation 210 is determined to be a sub-operation within operation 205 where a semiconductor layer, which would have the second composition in the alternating sequence, is formed using a third composition. The third composition has a higher germanium concentration than the second composition. In some embodiments, the semiconductor layer includes pure germanium, e.g., an atomic percentage of germanium of at least 95%. In some embodiments, the semiconductor layer includes silicon germanium. In some embodiments, an atomic percentage of germanium in the semiconductor layer ranges from about 60% to about 90%. In some embodiments, the semiconductor layer is grown by a process such as VPE or MBE, deposited by a process such as CVD process, an ALD process, or the like. In some embodiments, the semiconductor layer is formed using a same process as that used to form the semiconductor layers having the second composition. In some embodiments, the semiconductor layer is formed using a different process from that used to form the semiconductor layers having the second composition. In some embodiments, the operation 210 is usable to form the semiconductor layer 110 (FIG. 1).

In operation 215, a polysilicon layer is deposited over the semiconductor layer stack that includes the semiconductor layer. In some embodiments, the polysilicon layer is deposited using CVD, PECVD, ALD, or another suitable deposition process. The polysilicon layer is usable to form dummy gate structures.

In operation 220, the polysilicon layer is patterned to define openings that expose a surface of the semiconductor layer stack. In some embodiments, the patterning process includes a photolithography process in combination with one or more etching processes. In some embodiments, a combination of the operation 215 and the operation 220 is usable to form the mask material 155 or the mask material 135 (FIG. 1).

In operation 225, gate spacers are formed along sidewalls of the patterned polysilicon layer. The gate spacers are formed by depositing a dielectric material into the openings formed in operation 220 and then etching the dielectric material. In some embodiments, the etching includes isotropic etching. In some embodiments, the etching includes anisotropic etching. In some embodiments, the gate spacers include a single layer structure. In some embodiments, the gate spacers include a multiple layer structure. In some embodiments, the gate spacers include silicon oxide, silicon nitride, silicon oxynitride, combinations thereof, or other suitable materials. In some embodiments, a combination of the operations 215 and 220 along with the operation 225 is usable to form the mask material 155 or the mask material 135 (FIG. 1).

In some embodiments, the operation 225 is omitted. Omitting the operation 225 simplifies the method 200. However, omitting the operation 225 increases a difficulty of integrating formation of a stack PIN diode with a CFET device. In some embodiments, the operation 225 is performed after the operation 230, described below.

In operation 230, a first dopant type is implanted into the semiconductor layer stack. The implantation forms wells in the semiconductor layer stack at locations determined by the openings patterned polysilicon layer. In some embodiments, the first dopant type is p-type. In some embodiments, the first dopant type is n-type. In some embodiments, a dopant dose for operation 230 ranges from 1×10¹²cm⁻² to about 5×10¹⁶ cm⁻². In some embodiments, a dopant species used in operation 230 includes boron, indium, gallium, or another suitable p-type dopant. In some embodiments, a dopant species used in operation 230 includes phosphorous, arsenic, antimony, or another suitable n-type dopant In some embodiments, the implantation process for operation 230 uses an ion beam energy in a range, for example, from approximately 1 KeV to approximately 15 KeV. The dopants are implanted the semiconductor layer stack, for example, in a range from about 5 nm to about 20 nm. In some embodiments, a dopant concentration of wells formed by operation 230 ranges, for example, from about 1×10¹⁹ cm⁻³ to about 1×10²¹ cm⁻³. In some embodiments, the implantation process is followed by an annealing process. In some embodiments, implantation of dopants into the semiconductor layer stack is not followed with a post-anneal. In some embodiments, the operation 230 is usable to form the n-type wells 140 or the p-type wells 120 (FIG. 1).

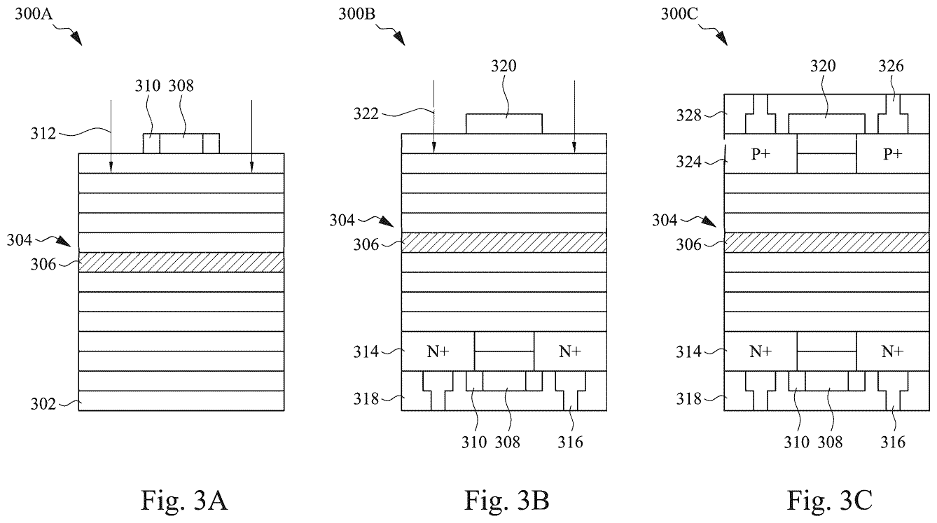

FIG. 3A is a cross-sectional view of a stacked PIN diode 300A following the operation 230 in accordance with some embodiments. The stacked PIN diode 300A includes a substrate 302. A semiconductor layer stack 304 is over the substrate 302. The semiconductor layer stack 304 includes a semiconductor layer 306. In some embodiments, the semiconductor layer stack 304 corresponds to the stack 105 of alternating semiconductor layers (FIG. 1). A patterned polysilicon layer 308 is over the semiconductor layer stack 304. Gate spacers 310 are along sidewalls of the patterned polysilicon layer 308. In some embodiments, the gate spacers 310 are omitted. In some embodiments, the patterned polysilicon layer 308 corresponds to the mask material 135 or the mask material 155 (FIG. 1). In some embodiments, a combination of the patterned polysilicon layer 308 and the gate spacers 310 corresponds to the mask material 135 or the mask material 155 (FIG. 1). An implantation process 312 is used to implant dopants of the first type into the semiconductor layer stack 304. In some embodiments, the implantation process is usable for form p-type wells 120 or n-type wells 140 (FIG. 1). In some embodiments, the gate spacers 310 are formed after the implantation process 312.

Returning to method 200, in operation 235, first contact structures are formed on a surface of the semiconductor layer stack. A dielectric layer is deposited along the surface of the semiconductor layer stack. In some embodiments, the dielectric layer covers the patterned polysilicon layer. In some embodiments, a top surface of the dielectric layer is substantially coplanar with the top surface of the patterned polysilicon layer. The dielectric layer is patterned to define openings exposing at least a portion of the wells formed by operation 230. Conductive material is then deposited into the openings in the dielectric layer to electrically connect to the wells formed by operation 230. In some embodiments, a silicidation process is performed in order to enhance the electrical connection between the contact structures and the wells formed by the operation 230.

In some embodiments, the dielectric layer includes silicon oxide, silicon carbide, silicon oxynitride, silicon oxycarbide, combinations thereof, or other suitable dielectric materials. In some embodiments, the dielectric layer is formed using CVD, PECVD, ALD, or another suitable deposition process. In some embodiments, the dielectric layer corresponds to the first dielectric layer 125 or the second dielectric layer 145 (FIG. 1).

In some embodiments, the contact structures have a stepped profile, a tapered profile or substantially parallel sidewalls. In some embodiments, the conductive material includes copper, aluminum, tungsten, cobalt, alloys thereof, or other suitable conductive materials. In some embodiments, the conductive material is deposited using physical vapor deposition (PVD), CVD, ALD, or other suitable deposition processes. In some embodiments, the forming of the contact structures includes depositing diffusion barriers prior to depositing the conductive material to help prevent diffusion of the conductive material into the dielectric layer. In some embodiments, the operation 235 is usable to form the contact structures 130 or the contact structures 150 (FIG. 1).

In operation 240, the structure is flipped. Flipping the structure includes rotating the structure such that the substrate is an uppermost surface of the structure. In some embodiments, a carrier is attached to the dielectric layer formed in operation 235 to facilitate flipping the structure. In some embodiments, the carrier is temporarily attached using an adhesive or other suitable attachment means. In some embodiments, the carrier remains attached to the dielectric layer until formation of the stacked PIN diode is completed. In some embodiments, the carrier is removed from the dielectric layer following the flipping. In some embodiments, the carrier is removed using a solution to dissolve the adhesive.

In operation 245, the substrate is removed. Removing the substrate exposes a surface of the semiconductor layer stack on the opposite side from the wells formed in operation 230. Exposing this surface of the semiconductor layer stack permits processing of the semiconductor layer stack to form the stacked arrangement for the stacked PIN diode. In some embodiments, the substrate is removed by grinding, chemical mechanical planarization (CMP), etching, or a combination thereof.

In operation 250, an implantation mask is formed on the surface of the semiconductor layer stack exposed by the removal of the substrate. The implantation mask includes openings that expose portions of the semiconductor layer stack for implanting of doped wells on in an opposite surface of the semiconductor layer stack from the wells formed in operation 230. In some embodiments, the implantation mask includes a deposition or formation process followed by a patterning process. In some embodiments, the implantation mask includes a photoresist, silicon nitride, silicon oxynitride, or other suitable materials. In some embodiments, the implantation mask is a single layer. In some embodiments, the implantation mask is multiple layers. In some embodiments, the implantation mask includes a hard mask underlying, e.g., the photoresist. In some embodiments, the hard mask includes titanium nitride, cobalt nitride, silicon nitride or another suitable material. In some embodiments, the pattern process includes a photolithography and etching process.

In some embodiments, the implantation mask is removed from the semiconductor layer stack following the implantation in operation 255, described below. In some embodiments, the implantation mask is maintained on the semiconductor layer stack following the implantation in operation 255.

In operation 255, a second implantation process is performed on the semiconductor layer stack. The implantation is performed using the implantation mask formed in operation 250 to determine the location of implantation into the semiconductor layer stack. The implantation process in operation 255 includes implanting dopants having an opposite dopant type from the dopants implanted in the operation 230. In some embodiments, the wells formed by the implantation operation 255 are aligned in the vertical direction with the wells formed by the implantation operation 230. In some embodiments, the second dopant type is p-type. In some embodiments, the second dopant type is n-type. In some embodiments, a dopant dose for operation 255 ranges from 1×10¹² cm⁻² to about 5×10¹⁶ cm⁻². In some embodiments, the dopant dosage for operation 255 is a same dopant dosage as that used in operation 230. In some embodiments, the dopant dosage for operation 255 is different from that used in operation 230. In some embodiments, a dopant species used in operation 255 includes boron, indium, gallium, or another suitable p-type dopant. In some embodiments, a dopant species used in operation 255 includes phosphorous, arsenic, antimony, or another suitable n-type dopant In some embodiments, the implantation process for operation 255 uses an ion beam energy in a range, for example, from approximately 1 KeV to approximately 15 KeV. The dopants are implanted the semiconductor layer stack, for example, in a range from about 5 nm to about 20 nm. In some embodiments, the implantation depth for operation 255 is a same depth as the implantation depth for operation 230. In some embodiments, the implantation depth for operation 255 is different from the implantation depth for operation 230. In some embodiments, a dopant concentration of wells formed by operation 255 ranges, for example, from about 1×10¹⁹ cm⁻³ to about 1×10²¹ cm⁻³. In some embodiments, the dopant concentration of the wells formed by the operation 255 is a same dopant concentration as the wells formed in operation 230. In some embodiments, the dopant concentration of the wells formed by the operation 255 is a different dopant concentration from the wells formed in operation 230. In some embodiments, the implantation process is followed by an annealing process. In some embodiments, implantation of dopants into the semiconductor layer stack is not followed with a post-anneal. In some embodiments, the operation 255 is usable to form the n-type wells 140 or the p-type wells 120 (FIG. 1).

FIG. 3B is a cross-sectional view of a stacked PIN diode 300B following the operation 255 in accordance with some embodiments. For the sake of brevity, only differences between stacked PIN diode 300A (FIG. 3A) and stacked PIN diode 300B are described. The stacked PIN diode 300B is rotated 180-degrees, i.e., flipped, relative to the stacked PIN diode 300A (FIG. 3A). In comparison with the stacked PIN diode 300A (FIG. 3A), the wells 314 formed by the implantation process 312 (FIG. 3A) is included in the stacked PIN diode 300B. In some embodiments, the wells 314 correspond to the n-type wells 140 (FIG. 1). The stacked PIN diode 300B further includes contact structures 316 extending through dielectric layer 318. In some embodiments, the contact structures 316 and dielectric layer 318 are formed in the operation 235 (FIG. 2). In some embodiments, the contact structures 316 correspond to the contact structures 150 or the contact structures 130 (FIG. 1). In some embodiments, the dielectric layer 318 corresponds to the first dielectric layer 125 or the second dielectric layer 145 (FIG. 1).

The stacked PIN diode 300B further includes an implantation mask 320 on a surface of the semiconductor layer stack 304 opposite the wells 314. In some embodiments, the implantation mask 320 includes a photoresist, silicon nitride, silicon oxynitride, or other suitable materials. In some embodiments, the implantation mask is a single layer. In some embodiments, the implantation mask 320 is multiple layers. In some embodiments, the implantation mask 320 includes a hard mask underlying, e.g., the photoresist. In some embodiments, the hard mask includes titanium nitride, cobalt nitride, silicon nitride or another suitable material. The stacked PIN diode 300B is also free of the substrate 302 (FIG. 3A). An implantation process 322 is performed on the portions of the semiconductor layer stack 304 exposed by the implantation mask 320. In some embodiments, the implantation process 322 is usable to form the n-type wells 140 or the p-type wells 120 (FIG. 1).

Returning to the method 200, in operation 260, second contact structures are formed over the surface of the semiconductor layer stack implanted during the operation 255. A dielectric layer is deposited along the surface of the semiconductor layer stack. In some embodiments, the dielectric layer covers the implantation mask. In some embodiments, a top surface of the dielectric layer is substantially coplanar with the top surface of the implantation mask. The dielectric layer is patterned to define openings exposing at least a portion of the wells formed by operation 255. Conductive material is then deposited into the openings in the dielectric layer to electrically connect to the wells formed by operation 255. In some embodiments, a silicidation process is performed in order to enhance the electrical connection between the contact structures and the wells formed by the operation 255.

In some embodiments, the dielectric layer includes silicon oxide, silicon carbide, silicon oxynitride, silicon oxycarbide, combinations thereof, or other suitable dielectric materials. In some embodiments, the dielectric layer is formed using CVD, PECVD, ALD, or another suitable deposition process. In some embodiments, the dielectric layer corresponds to the first dielectric layer 125 or the second dielectric layer 145 (FIG. 1).

In some embodiments, the contact structures have a stepped profile, a tapered profile or substantially parallel sidewalls. In some embodiments, the conductive material includes copper, aluminum, tungsten, cobalt, alloys thereof, or other suitable conductive materials. In some embodiments, the conductive material is deposited using physical vapor deposition (PVD), CVD, ALD, or other suitable deposition processes. In some embodiments, the forming the contact structures includes depositing diffusion barriers prior to depositing the conductive material to help prevent diffusion of the conductive material into the dielectric layer. In some embodiments, the operation 260 is usable to form the contact structures 130 or the contact structures 150 (FIG. 1).

FIG. 3C is a cross-sectional view of a stacked PIN diode 300C following operation 260 in accordance with some embodiments. For the sake of brevity, only differences between stacked PIN diode 300B (FIG. 3B) and stacked PIN diode 300C are described. The stacked PIN diode 300C includes contact structures 326 extending through dielectric layer 328. In some embodiments, the contact structures 326 and dielectric layer 328 are formed in the operation 260 (FIG. 2). In some embodiments, the contact structures 326 correspond to the contact structures 150 or the contact structures 130 (FIG. 1). In some embodiments, the dielectric layer 328 corresponds to the first dielectric layer 125 or the second dielectric layer 145 (FIG. 1).

Returning to the method 200, one of ordinary skill in the art would recognize that modifications to the method 200 are within the scope of this description. In some embodiments, at least one additional operation is performed in the method 200. For example, in some embodiments, a removal process for removing the implantation mask formed in operation 250 is included in the method 200. In some embodiments, at least one operation of the method 200 is omitted. For example, in some embodiments, the formation of the gate spacers in operation 225 is omitted. In some embodiments, an order of operations of the method 200 is modified. For example, in some embodiments, the operations 205 and 210 are performed together.

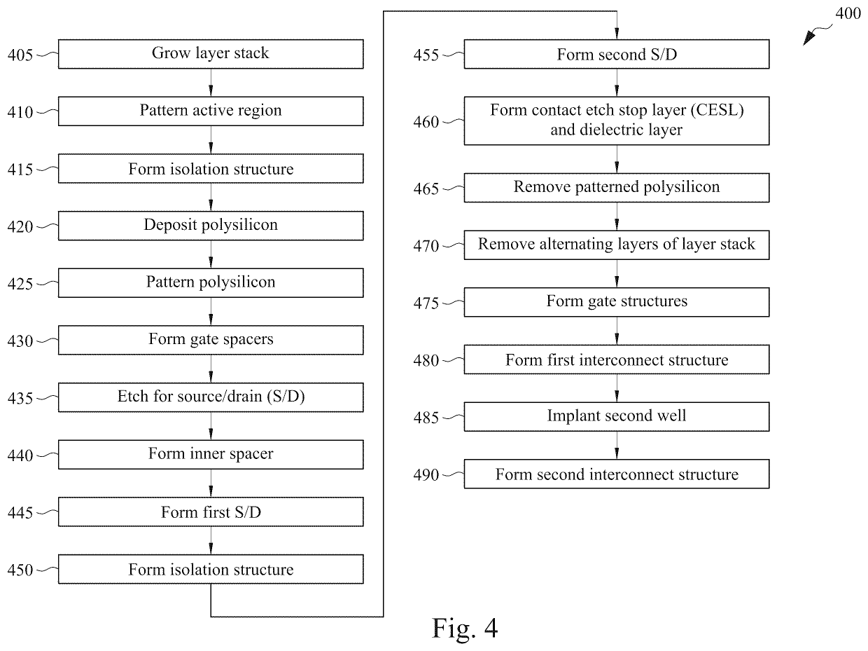

FIG. 4 is a flowchart of a method 400 of making a stacked PIN diode simultaneously with a complementary field effect transistor (CFET) in accordance with some embodiments. In some embodiments, the method 400 is usable to form the stacked PIN diode 100 (FIG. 1). In some embodiments, the method 400 produces the intermediate products of any of stacked PIN diodes 300A-300C (FIGS. 3A-3C). In some embodiments, the method 400 is usable in combination with the method 200 (FIG. 2). During various operations of the method 400, a section of a workpiece where the stacked PIN diode is to be formed is masked to allow processing of the CFET device without impacting the structure of the stacked PIN diode. The method 400 facilitates the formation of a stacked PIN diode and one or more CEFT devices in a single manufacturing process. This helps to improve integration of devices in an IC and helps to reduce production complexity leading to improved efficiency in the manufacturing process.

In operation 405, a semiconductor layer stack is formed on a substrate. Forming the semiconductor layer stack includes forming alternating layers of semiconductor material. Each layer of the semiconductor layer stack has a different composition from each adjacent layer within the semiconductor layer stack. In some embodiments, each layer of the semiconductor layer stack is grown by a process such as VPE or MBE, deposited by a process such as CVD process, an ALD process, or the like. In some embodiments, each of the layers in the semiconductor layer stack is formed using a same process. In some embodiments, at least one layer of the semiconductor layer stack is formed using a different process from at least one other layer of semiconductor layer stack. In some embodiments, each layer of the semiconductor layer stack has a first composition is formed using a first process and each layer of the semiconductor layer stack having a second composition is formed using a second process, different from the first process.

The first composition includes silicon. In some embodiments, the first composition includes pure silicon, e.g., a silicon atomic percentage of 95% or more. In some embodiments, the first composition includes silicon with a low concentration of germanium. In some embodiments, an atomic percentage of germanium in the first composition is less than about 5%. The second composition silicon germanium. The germanium concentration in the second composition is greater than the germanium concentration in the first composition. In some embodiments, the atomic percentage of germanium in the second composition ranges from about 10% to about 50%. In some embodiments, the operation 205 forms the stack 105 of alternating semiconductor layers 105 (FIG. 1).

In operation 410, active regions are patterned. The active regions define source/drain diffusion regions for an IC device. The active region includes a doped portion of the semiconductor layer stack. In some embodiments, the doping is performed by ion implantation. In some embodiments, the doping is performed by in-situ doping during formation of the semiconductor layer stack.

In operation 415, an isolation structure is formed surrounding the patterned active regions. The isolation structure is usable to electrically separate one device from an adjacent device. In some embodiments, the isolation structure includes a shallow trench isolation (STI) structure. In some embodiments, the isolation structure is formed by removing a portion of the semiconductor layer stack to define an opening and depositing a dielectric material into the opening. In some embodiments, the dielectric material includes a single dielectric material. In some embodiments, the dielectric material includes a plurality of layers of one or more dielectric compositions. In some embodiments, the dielectric material includes silicon oxide, silicon nitride, silicon oxynitride or other suitable dielectric materials.

In operation 420, a polysilicon layer is deposited over the semiconductor layer stack that includes the semiconductor layer. In some embodiments, the polysilicon layer is deposited using CVD, PECVD, ALD, or another suitable deposition process. The polysilicon layer is usable to form dummy gate structures.

In operation 425, the polysilicon layer is patterned to define openings that expose a surface of the semiconductor layer stack. In some embodiments, the patterning process includes a photolithography process in combination with one or more etching processes. In some embodiments, a combination of the operation 420 and the operation 425 is usable to form the mask material 155 or the mask material 135 (FIG. 1).

Up to this point of method 400 includes processing of sections of the workpiece for both a CFET device and a stacked PIN diode without masking the stacked PIN diode section of the workpiece.

In operation 430, gate spacers are formed along sidewalls of the patterned polysilicon layer. The gate spacers are formed by depositing a dielectric material into the openings formed in operation 425 and then etching the dielectric material. In some embodiments, the etching includes isotropic etching. In some embodiments, the etching includes anisotropic etching. In some embodiments, the gate spacers include a single layer structure. In some embodiments, the gate spacers include a multiple layer structure. In some embodiments, the gate spacers include silicon oxide, silicon nitride, silicon oxynitride, combinations thereof, or other suitable materials. In some embodiments, a combination of the operations 420 and 425 along with the operation 430 is usable to form the mask material 155 or the mask material 135 (FIG. 1).

In some embodiments, the stacked PIN diode section of the workpiece is masked during the operation 430. Masking the stacked PIN diode section of the workpiece prevents formation of the gate spacers along the sidewalls in the stacked PIN diode section, but permits formation of the formation of the gate spacers in the CFET section of the work piece.

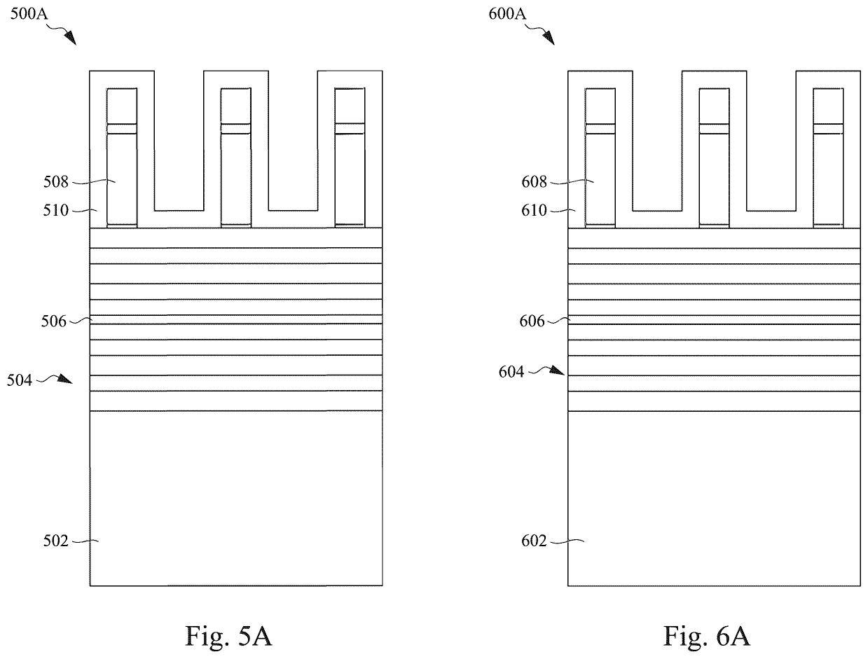

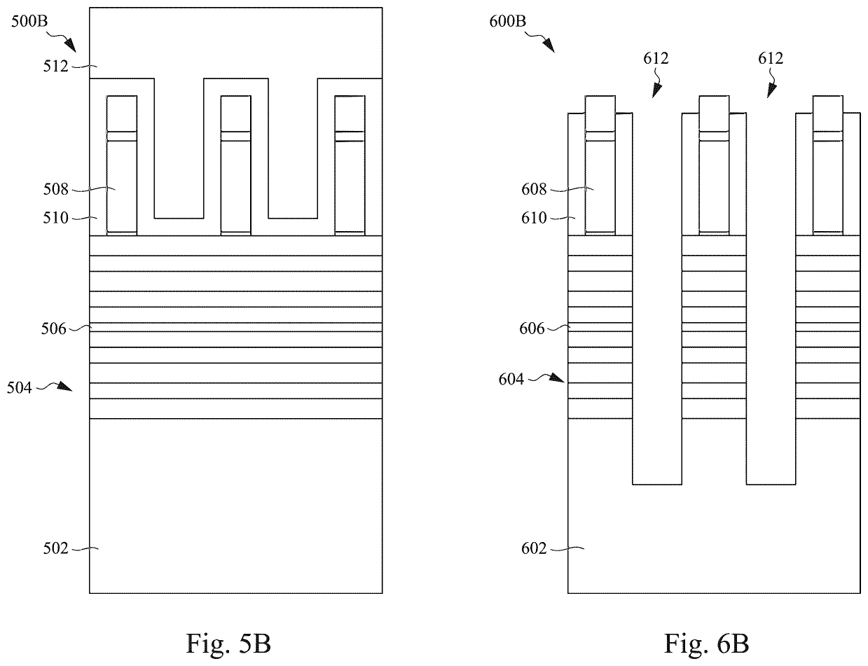

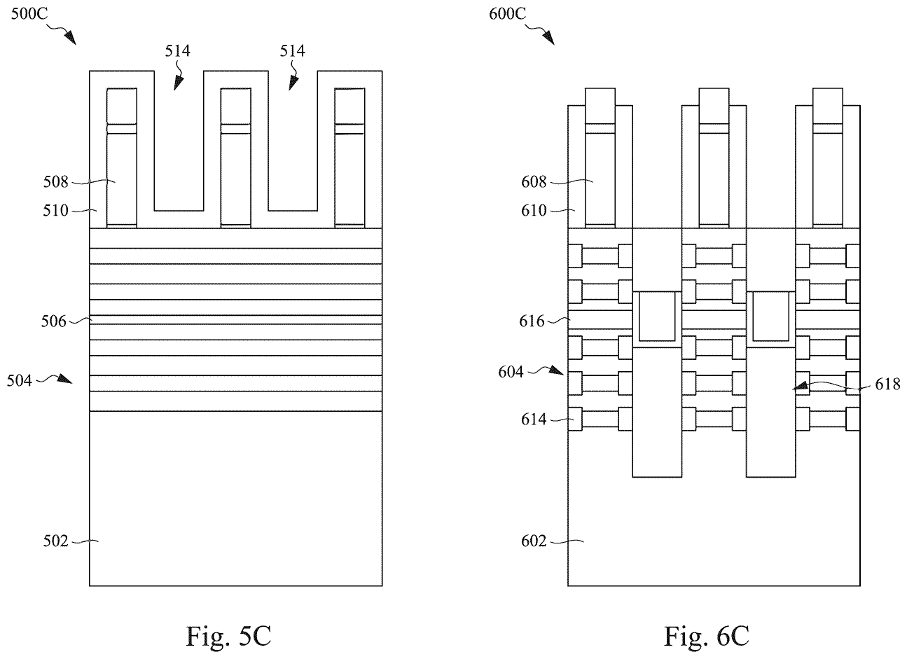

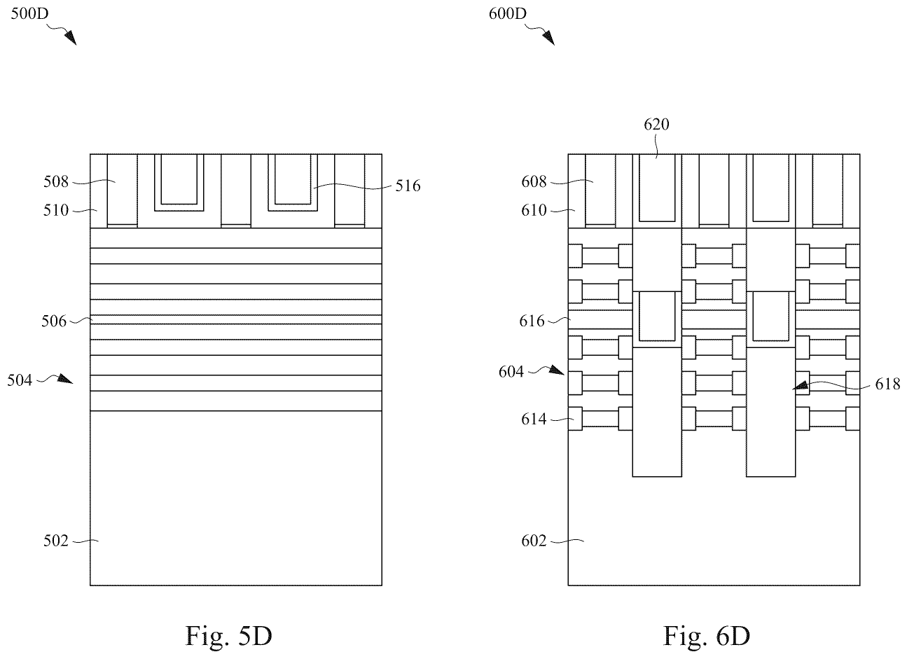

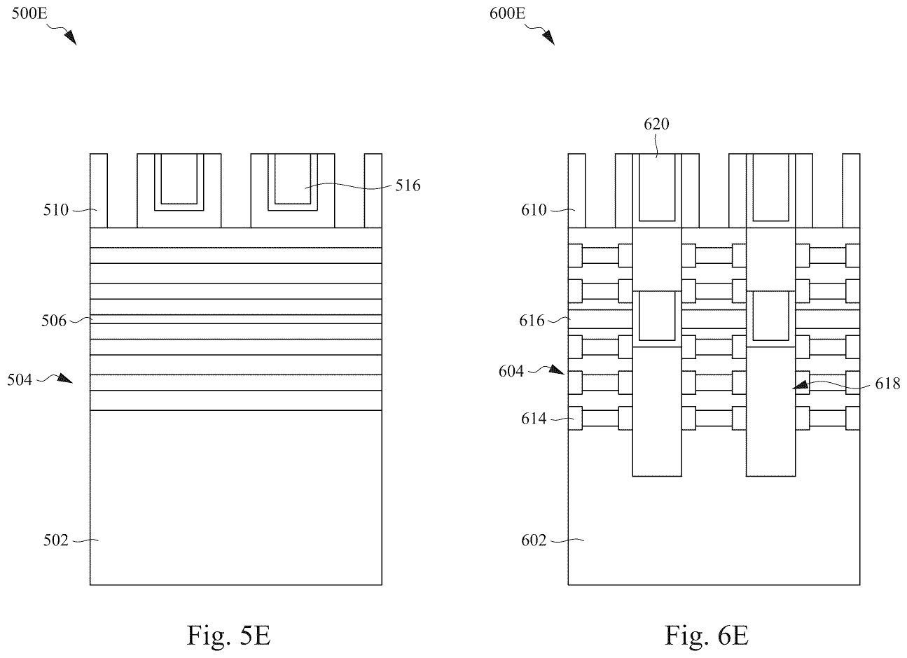

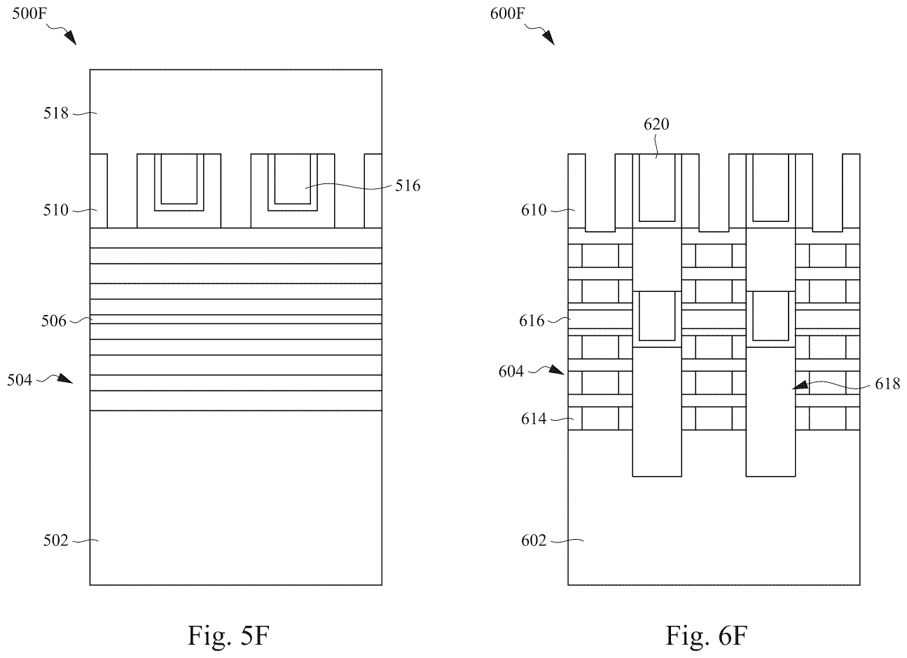

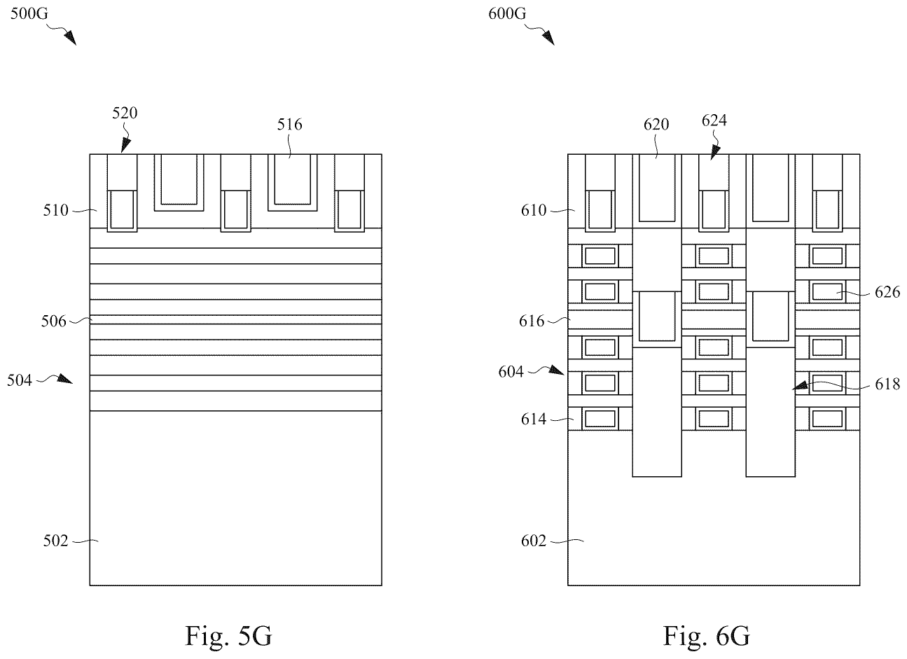

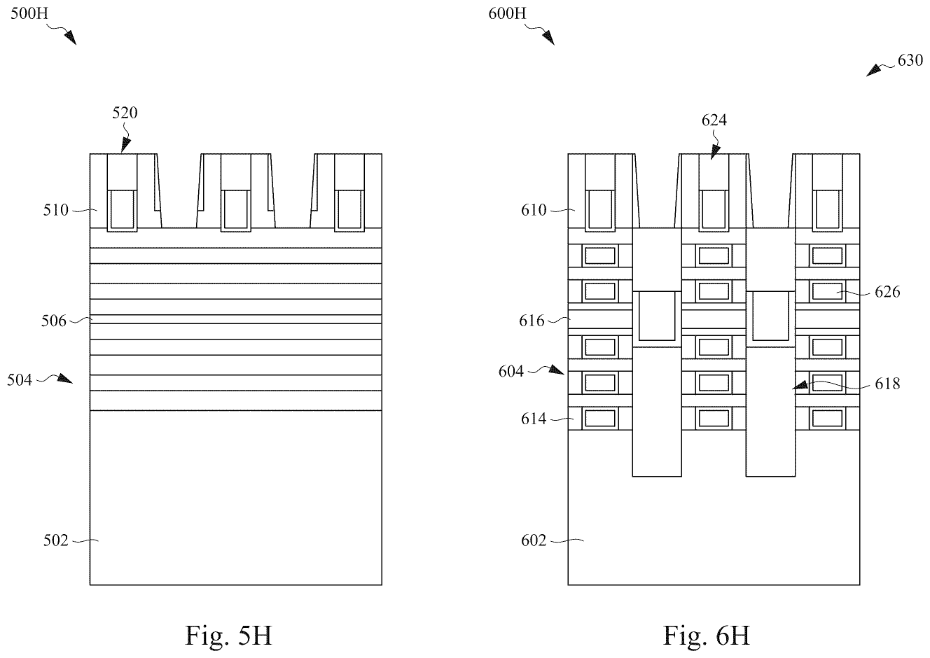

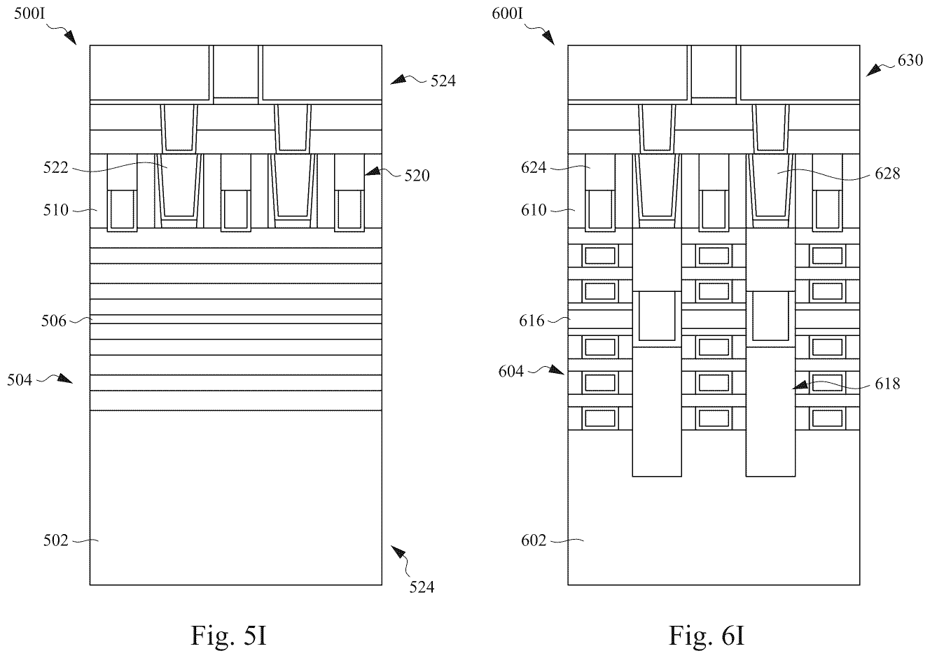

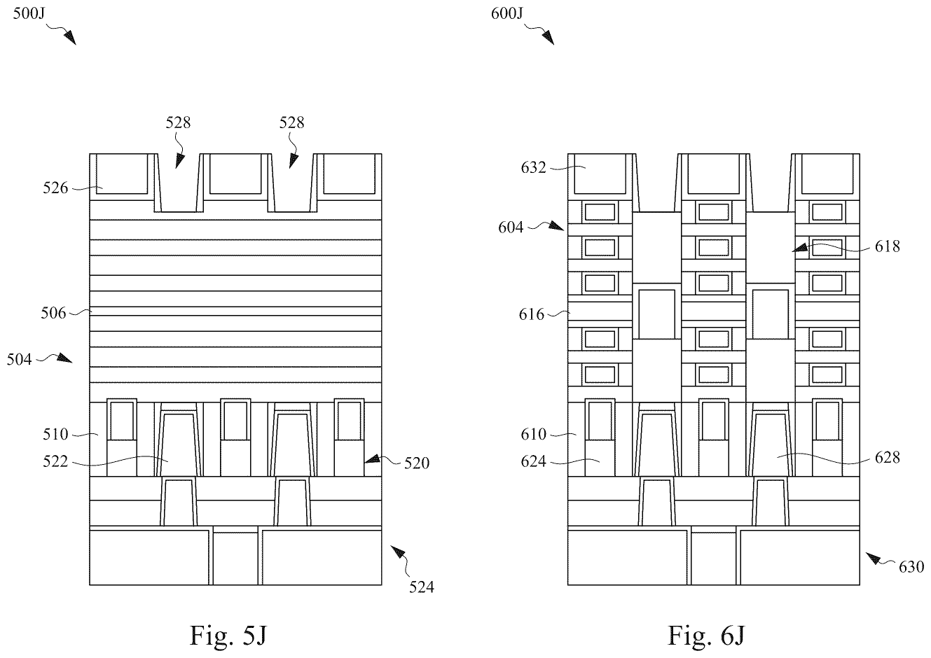

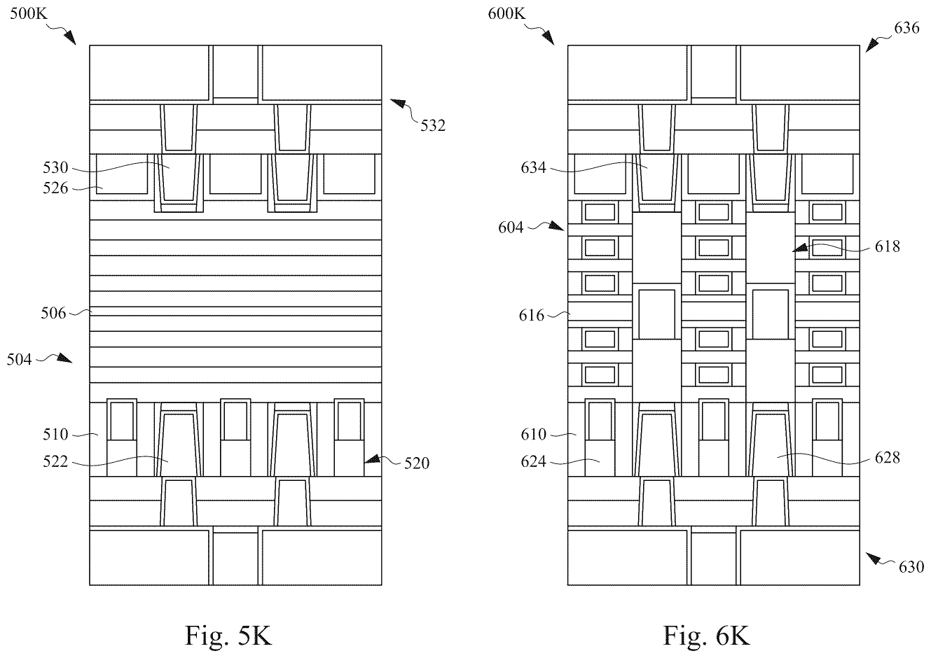

FIG. 5A is a cross-sectional view of a stacked PIN diode 500A following operation 430 in accordance with some embodiments. The stacked PIN diode 500A includes a substrate 502. A semiconductor layer stack 504 is over the substrate. The semiconductor layer stack 504 includes alternating layers of semiconductor material, where each layer has a different composition from adjacent layers. In some embodiments, the semiconductor layer stack 504 corresponds to the stack 105 of alternating semiconductor layers (FIG. 1). The semiconductor layer stack 504 includes a semiconductor layer 506. The semiconductor layer 506 includes germanium. In some embodiments, the semiconductor layer 506 further includes silicon. In some embodiments, the semiconductor layer 506 further includes dopants, such as n-type dopants or p-type dopants. A patterned polysilicon layer 508 is over the semiconductor layer stack 504. A gate spacer layer 510 is over the patterned polysilicon layer 508. The stacked PIN diode 500A does not include etching of the gate spacer layer 510 to remove the gate spacer layer from the top of the patterned polysilicon layer 504 or along the surface of the semiconductor layer stack 504. The stacked PIN diode 500A includes various other layers, such as mask layers that are not labeled for the sake of simplicity of the drawing and brevity.

FIG. 6A is a cross-sectional view of a CFET 600A following operation 430 in accordance with some embodiments. The CFET 600A includes a substrate 602. A semiconductor layer stack 604 is over the substrate. The semiconductor layer stack 604 includes alternating layers of semiconductor material, where each layer has a different composition from adjacent layers. In some embodiments, the semiconductor layer stack 604 corresponds to the stack 105 of alternating semiconductor layers (FIG. 1). The semiconductor layer stack 604 includes a semiconductor layer 606. A patterned polysilicon layer 608 is over the semiconductor layer stack 604. A gate spacer layer 610 is over the patterned polysilicon layer 608. The CFET 600A does not include etching of the gate spacer layer 610 to remove the gate spacer layer from the top of the patterned polysilicon layer 604 or along the surface of the semiconductor layer stack 604. The CFET 600A includes various other layers, such as mask layers that are not labeled for the sake of simplicity of the drawing and brevity.

Returning to the method 400 (FIG. 4), in operation 435 an etching to define openings for source/drain (S/D) features is performed. The etching is performed on the CFET device, while the stacked PIN diode section of the workpiece is masked during the etching process. The etching process defines openings extending through the semiconductor layer stack. In some embodiments, the etching process forms a recess in the substrate. In some embodiments, photolithography is used to determine the location of the openings. In some embodiments, the etching includes a wet etching process.

FIG. 5B is a cross-sectional view of a stacked PIN diode 500A following operation 435 in accordance with some embodiments. In comparison with the stacked PIN diode 500A (FIG. 5A), the stacked PIN diode 500B includes a mask layer 512 over a top surface of the gate spacer layer 510 in order to protect the stacked PIN diode 500B during the etching process of operation 435 (FIG. 4). In some embodiments, the mask layer 512 includes a photoresist. In some embodiments, the mask layer 512 includes multiple layers, such as a hard mask below the photoresist.

FIG. 6B is a cross-sectional view of a CFET 600B following operation 435 in accordance with some embodiments. In comparison with the CFET 600A (FIG. 6A), the CFET 600B includes openings 612 extending through the semiconductor layer stack 604. The openings 612 define recesses in the substrate 602. In some embodiments, the openings 612 do not form recesses in the substrate 602.

Returning to the method 400 (FIG. 4), in operation 440 an inner spacer is formed. An inner spacer is formed along sidewalls of the silicon germanium layers of the semiconductor layer stack and separates the silicon germanium layers of the semiconductor layer stack from the openings formed in operation 435. The inner spacer is also interposed between the lower portion of a later formed active gate structure and the later formed S/D structure. In some embodiments, the inner spacer includes insulative material, for example, silicon nitride, silicon oxide, silicon carbide nitride, silicon oxycarbonnitride, silicon oxynitride, or another suitable dielectric material.

In addition to forming the inner spacers, a semiconductor layer is formed in the operation 440. The semiconductor layer is formed by removing an entirety of a layer of the semiconductor layer stack and replacing the layer with the dielectric material of the inner spacers. Since the stacked PIN diode section of the workpiece is masked during the operation 440, the semiconductor layer in the stacked PIN diode section of the workpiece is not replaced during the operation 440.

In operation 445, a first S/D structure is formed in the opening formed by the operation 435. The first S/D structure is closest to the substrate. In some embodiments, the first S/D structure is within the recess in the substrate formed in operation 435. In some embodiments, the first S/D structure is formed by epitaxially growing a semiconductor material, such as silicon or silicon germanium. The semiconductor material is doped using a first type of dopants, e.g., p-type dopants or n-type dopants. In some embodiments, the semiconductor material is doped using an ion implantation process. In some embodiments, the semiconductor material is doped using an in-situ doping process. In some embodiments, an annealing process is performed following doping of the semiconductor material.

In operation 450, an isolation structure is formed over the first S/D structure. The isolation structure is a dielectric material to electrically separate the first S/D structure formed in operation 445 from a later formed second S/D structure. In some embodiments, the isolation structure includes silicon oxide, silicon nitride, silicon oxynitride, or another suitable dielectric material. In some embodiments, the isolation structure is formed by CVD, ALD, or another suitable deposition process. In some embodiments, the isolation structure is a single material. In some embodiments, the isolation structures include multiple material layers, e.g., having different compositions.

In operation 455, a second S/D structure is formed on the isolation structure in the opening formed by the operation 435. The second S/D structure is farthest from the substrate. In some embodiments, the second S/D structure is formed by epitaxially growing a semiconductor material, such as silicon or silicon germanium. The semiconductor material is doped using a second type of dopants, e.g., p-type dopants or n-type dopants. The second type of dopants is opposite to the first type of dopants. In some embodiments, the semiconductor material is doped using an ion implantation process. In some embodiments, the semiconductor material is doped using an in-situ doping process. In some embodiments, an annealing process is performed following doping of the semiconductor material. In some embodiments, a single anneal process is performed following doping of each of the first S/D structure and the second S/D structure.

Further, during the operation 455, first doped wells are formed in the stacked PIN diode section of the workpiece. In some embodiments, the first doped wells are usable to form the n-type wells 140 or the p-type wells 120 (FIG. 1). In some embodiments, the ion implantation process in operation 455 is similar to the operation 230 of method 200 (FIG. 2). In some embodiments, the first doped wells are formed simultaneously with the doping of the second S/D structures. In some embodiments, the first doped wells are formed by a separate doping process from that used to form the second S/D structures.

The stacked PIN diode section of the workpiece remains masked during the operations 435-450. In some embodiments, the mask layer over the stacked PIN diode section of the workpiece is removed during a doping process performed in operation 455, i.e., when the doping process for forming the first well is simultaneous to the doping of the second S/D structures. In some embodiments, the mask layer over the stacked PIN diode is removed following the doping of the second S/D structures. The first wells are formed following the removal of the mask layer. In some embodiments, the CFET section of the workpiece is masked during the formation of the first wells, e.g., when the doping process for forming the first well is after the doping of the second S/D structures.

FIG. 5C is a cross-sectional view of a stacked PIN diode 500C following operation 455 in accordance with some embodiments. In comparison with the stacked PIN diode 500B (FIG. 5B), the stacked PIN diode 500C does not include the mask layer 512 over a top surface of the gate spacer layer 510. In some embodiments, the mask layer 512 is removed using an etching process, a dissolution process, an ashing process or another suitable removal process. An ion implantation operation 514 is performed to implant the first wells in the stacked PIN diode 500C. In some embodiments, the ion implantation process 514 is usable to form the n-type wells 140 or the p-type wells 120 (FIG. 1). A depth of the wells formed using the implantation process 514 is controllable based on a duration and an energy of the implantation process 514. A maximum depth of the wells resulting from the implantation process 514 is less than a distance from the surface of semiconductor layer stack 504 to the semiconductor layer 506.

FIG. 6C is a cross-sectional view of a CFET 600C following operation 455 in accordance with some embodiments. In comparison with the CFET 600B (FIG. 6B), the CFET 600C includes S/D structures 618 in the openings 612. The S/D structures 618 include a first S/D structure, e.g., formed by the operation 445 (FIG. 4), an isolation structure, e.g., formed by the operation 450 (FIG. 4), and a second S/D structure, e.g., formed by the operation 455 (FIG. 4). The individual components of the S/D structures 618 are not labeled for clarity of the drawings and brevity. The CFET 600C further includes inner spacers 614 along sidewalls of alternating layers of the semiconductor layer stack 604. The inner spacers 614 separate the S/D structures 618 from the alternating layers of the semiconductor layer stack 604. The CFET 600C further includes an isolation layer 616. The isolation layer 616 includes a similar material as the inner spacers 614; however, an entirety of the corresponding semiconductor layer of the semiconductor layer stack 604 is replaced by the dielectric material to form the isolation layer 616.

Returning to the method 400 (FIG. 4), in operation 460 a contact etch stop layer (CESL) is formed. An inter layer dielectric layer (ILD) is also formed over the CESL; and a planarization process is performed. The CESL and the ILD are formed a space between adjacent polysilicon structures. Each of the CESL and the ILD include a dielectric material; however, the dielectric material of the CESL is different from the dielectric material of the ILD. In some embodiments, the CESL and the ILD independently include silicon oxide, silicon nitride, silicon oxynitride or another suitable dielectric material. In some embodiments, the CESL is formed over a portion of the gate spacer layer extending along a surface of the semiconductor layer stack. In some embodiments, the portion of the gate spacer layer extending along the surface of the semiconductor layer stack is removed prior to the formation of the CESL. In some embodiments, the CESL and the ILD are independently formed by CVD, ALD, or another suitable deposition process.

The planarization process is used to planarize a top-most surface of the workpiece. In some embodiments, the planarization process includes a CMP process, an etching process, a combination thereof, or another suitable removal process. The stacked PIN diode section of the workpiece is unmasked for the operation 460.

FIG. 5D is a cross-sectional view of a stacked PIN diode 500D following operation 460 in accordance with some embodiments. In comparison with the stacked PIN diode 500C (FIG. 5C), the stacked PIN diode 500D includes dielectric regions 516. The dielectric regions 516 include a CESL and an ILD. The individual components of the dielectric regions 516 are not labeled for clarity of the drawings and brevity. The gate spacer layer 510 remains between the dielectric regions 516 and the semiconductor layer stack 504. In some embodiments, the gate spacer layer 510 is removed and the dielectric regions 516 directly contact the semiconductor layer stack 504. A top-most surface of the stacked PIN diode 500D is planar due to the planarization process.

FIG. 6D is a cross-sectional view of a CFET 600D following operation 460 in accordance with some embodiments. In comparison with the CFET 600C (FIG. 6C), the CFET 600D includes dielectric regions 620. The dielectric regions 620 include a CESL and an ILD. The individual components of the dielectric regions 620 are not labeled for clarity of the drawings and brevity. The gate spacer layer 610 remains between the dielectric regions 620 and the semiconductor layer stack 604. In some embodiments, the gate spacer layer 610 is removed and the dielectric regions 620 directly contact the semiconductor layer stack 604. A top-most surface of the CFET 600D is planar due to the planarization process.

Returning to method 400 (FIG. 4), in operation 465, the patterned polysilicon is removed. In some embodiments, the patterned polysilicon is removed using a wet etching, an oxidation process or another suitable removal process. In some embodiments, removing the patterned polysilicon exposes portions of the semiconductor layer stack. In some embodiments where the dummy gate structure includes a gate dielectric, removing the patterned polysilicon exposes the gate dielectric. In some embodiments where the dummy gate structure includes a gate dielectric, the gate dielectric is also removed in the operation 465. In some embodiments, the stacked PIN diode section of the workpiece is masked during the removal of the patterned polysilicon. In some embodiments, the stacked PIN diode section of the workpiece is unmasked and the patterned polysilicon on the stacked PIN diode section is removed by operation 465.

FIG. 5E is a cross-sectional view of a stacked PIN diode 500E following operation 465 in accordance with some embodiments. In comparison with the stacked PIN diode 500D (FIG. 5D), the patterned polysilicon 508 is removed from the stacked PIN diode 500E.

FIG. 6E is a cross-sectional view of a CFET 600E following operation 465 in accordance with some embodiments. In comparison with the CFET 600D (FIG. 6D), the patterned polysilicon 608 is removed from the CFET 600E.

Returning to the method 400 (FIG. 4), in the operation 470 the silicon germanium layers of the semiconductor layer stack are removed. Removing the silicon germanium layers of the semiconductor layer stack defines openings between the inner spacers formed in operation 440 and expose surfaces of the silicon layers of the semiconductor layer stack. In some embodiments, an etching process selectively removes the silicon germanium layers with respect to silicon layers or the various dielectric layers in the CFET section of the workpiece. For example, the etching process is a dry etch, a wet etch, other suitable etch, or a combination thereof. In some embodiments, a patterned mask layer, e.g., an etch mask, is formed that protects the CESL, ILD and the top surface of the semiconductor layer stack during the etching process. The stacked PIN diode section of the workpiece is masked during the operation 470 so the silicon germanium layers in the semiconductor layer stack in the stacked PIN diode section of the workpiece remain following the operation 470.

FIG. 5F is a cross-sectional view of a stacked PIN diode 500F following operation 470 in accordance with some embodiments. In comparison with the stacked PIN diode 500E (FIG. 5E), the stacked PIN diode 500F includes a mask layer 518. In some embodiments, the mask layer 518 includes a same material as mask layer 512 (FIG. 5B). In some embodiments, the mask layer 518 includes a different material from the mask layer 512 (FIG. 5B).

FIG. 6F is a cross-sectional view of a CFET 600F following operation 470 in accordance with some embodiments. In comparison with the CFET 600E (FIG. 6E), the silicon germanium layers of the semiconductor layer stack 604 are removed defining gaps within the semiconductor layer stack 604 of the CFET 600F.

Returning to the method 400 (FIG. 4), in operation 475, gate structures are formed in the openings defined in operation 470. The gate structures include a gate dielectric, e.g., a high-k gate dielectric, and a conductive material. In some embodiments, the gate structure includes additional layers such as work function layers, barrier layers, or other suitable layers. In some embodiments, the gate dielectric layer is formed by CVD, ALD, PVD, or other suitable deposition processes. In some embodiments, the conductive material is formed by CVD, ALD, PVD, plating, or other suitable deposition processes. The operation 475 also forms a gate structure in the opening defined by the removal of the patterned polysilicon in operation 465. In some embodiments, the stacked PIN diode portion of the workpiece is masked during an entirety of the performance of the operation 475. In some embodiments, the stacked PIN diode section of the workpiece is masked during formation of the gate structures within the semiconductor layer stack and then unmasked for the formation of the gate structure in the opening defined by removal of the patterned polysilicon in operation 465.

FIG. 5G is a cross-sectional view of a stacked PIN diode 500G following operation 475 in accordance with some embodiments. In comparison with the stacked PIN diode 500F (FIG. 5F), the stacked PIN diode 500G includes a gate structure 520 filling the opening defined by the removal of the patterned polysilicon 508. The individual components of the gate structure 520 are not labeled for clarity of the drawing and brevity.

FIG. 6G is a cross-sectional view of a CFET 600G following operation 475 in accordance with some embodiments. In comparison with the CFET 600F (FIG. 6F), the CFET 600G includes a gate structure 624 filling the opening defined by the removal of the patterned polysilicon 608. The individual components of the gate structure 624 are not labeled for clarity of the drawing and brevity. The CFET 600G further includes gate structures 626 filling the openings defined by the removal of the silicon germanium portions of the semiconductor layer stack 604.

Returning to the method 400 (FIG. 4), in operation 480, a first interconnect structure is formed. The first interconnect structure is electrically connected to the first wells in the stacked PIN diode section of the workpiece. The first interconnect structure is electrically connected to the second S/D structures in the CFET section of the workpiece. One of ordinary skill in the art would understand that while the first interconnect structure as a whole is electrically connected to the first well and the second S/D structures, the first interconnect structure does not necessarily electrically connect the first well to the second S/D structures. The first interconnect structure is formed by removing the CESL and ILD formed in the operation 460 to expose the first well in the stacked PIN diode section of the workpiece and to expose the second S/D structures in the CFET section of the workpiece. A contact structure is then formed in the opening defined by the removal of the CESL and ILD. In some embodiments, the formation of the contact structure is similar to the operation 235 (FIG. 2). Formation of the first interconnect structure continues with the deposition of one or more dielectric layers, removal of portions of the dielectric layer(s) and formation of conductive materials in the resulting openings in the dielectric layer(s). The details of formation of the interconnect structure are not provided for the sake of brevity.

FIG. 5H is a cross-sectional view of a stacked PIN diode 500H during operation 480 in accordance with some embodiments. In comparison with the stacked PIN diode 500G (FIG. 5G), the dielectric regions 516 are removed in stacked PIN diode 500H to expose portions of the semiconductor layer stack 504.

FIG. 6H is a cross-sectional view of a CFET 600H during operation 480 in accordance with some embodiments. In comparison with the CFET 600G (FIG. 6G), the dielectric regions 620 are removed in CFET 600H to expose portions of the S/D structures 618.

FIG. 5I is a cross-sectional view of a stacked PIN diode 500I following operation 480 in accordance with some embodiments. In comparison with the stacked PIN diode 500H (FIG. 5H), the stacked PIN diode 500I includes contact structures 522 electrically connected to the first wells; and an interconnect structure 524 electrically connected to the contact structures 522.

FIG. 6I is a cross-sectional view of a CFET 600I following operation 480 in accordance with some embodiments. In comparison with the CFET 600H (FIG. 6H), the CFET 600I includes contact structures 628 electrically connected to the second S/D structure of the S/D structures 618. An interconnect structure 630 is electrically connected to the contact structures 628.

Returning to the method 400 (FIG. 4), in operation 485, the second well is implanted in the stacked PIN diode section of the workpiece. The operation 485 further includes flipping the workpiece and removing the substrate from the workpiece to expose a surface of the semiconductor layer stack opposite the first interconnect structure formed in operation 480. In some embodiments, the flipping of the workpiece is similar to the operation 240 (FIG. 2). In some embodiments, the removal of the substrate is similar to the operation 245 (FIG. 2).

Implanting of the second well includes formation of an implantation mask, e.g., operation 250 (FIG. 2). A second dopant is then implanted into the semiconductor layer stack in the stacked PIN diode section of the workpiece. In some embodiments, the implantation process is similar to the operation 255 (FIG. 2). In some embodiments, the CFET section of the workpiece is masked during an entirety of the operation 485. In some embodiments, the CFET section of the workpiece is unmasked for formation of the implantation mask and then masked for the implantation process.

FIG. 5J is a cross-sectional view of a stacked PIN diode 500J following operation 485 in accordance with some embodiments. In comparison with the stacked PIN diode 500I (FIG. 5I), the stacked PIN diode 500J includes implantation mask 526 on a surface of the semiconductor layer stack 504 opposite the interconnect structure 524. An implantation process 528 is performed on the portions of the semiconductor layer stack 504 exposed by the implantation mask 526. The stacked PN diode 500J does not include substrate 502. A depth of the wells formed using the implantation process 528 is controllable based on a duration and an energy of the implantation process 528. A maximum depth of the wells resulting from the implantation process 528 is less than a distance from the surface of the semiconductor layer stack 504 to the semiconductor layer 506.

FIG. 6J is a cross-sectional view of a CFET 600J following operation 485 in accordance with some embodiments. In comparison with the CFET 600I (FIG. 6I), the CFET 600J includes implantation mask 632. Openings in the implantation mask 632 expose the S/D structure 618. The CFET 600J does not include the substrate 602. In some embodiments, the implantation mask 632 includes a dummy gate structure.

Returning to the method 400 (FIG. 4), in operation 490, a second interconnect structure is formed. The second interconnect structure is electrically connected to the second wells in the stacked PIN diode section of the workpiece. The second interconnect structure is electrically connected to the first S/D structures in the CFET section of the workpiece. One of ordinary skill in the art would understand that while the second interconnect structure as a whole is electrically connected to the second well and the first S/D structures, the second interconnect structure does not necessarily electrically connect the second well to the first S/D structures. A contact structure is then formed in the opening defined by the implantation mask. In some embodiments, the formation of the contact structure is similar to the operation 260 (FIG. 2). Formation of the second structure continues with the deposition of one or more dielectric layers, removal of portions of the dielectric layer(s) and formation of conductive materials in the resulting openings in the dielectric layer(s). The details of formation of the interconnect structure are not provided for the sake of brevity.

FIG. 5K is a cross-sectional view of a stacked PIN diode 500K following operation 490 in accordance with some embodiments. In comparison with the stacked PIN diode 500J (FIG. 5J), the stacked PIN diode 500K includes contact structures 530 electrically connected to the second wells; and an interconnect structure 532 electrically connected to the contact structures 530.

FIG. 6K is a cross-sectional view of a CFET 600K following operation 490 in accordance with some embodiments. In comparison with the CFET 600J (FIG. 6J), the CFET 600K includes contact structures 634 electrically connected to the first S/D structure of the S/D structures 618. An interconnect structure 636 is electrically connected to the contact structures 634.

The method 400 is usable to simultaneously form both a CFET device and a stacked PIN diode. One of ordinary skill in the art would understand that modifications to the method 400 are within the skill of one of ordinary skill in the art. In some embodiments, at least one operation is added to the method 400. For example, in some embodiments, a workpiece flipping and/or substrate removal operation is included in the method 400. In some embodiments, at least one operation is omitted from the method 400. For example, in some embodiments, the operation 430 is omitted from the method 400. In some embodiments, an order of operations of the method 400 is adjusted. For example, in some embodiments, formation of the S/D structure is separated into a first process performed from a first surface of the semiconductor layer stack, e.g., prior to flipping the workpiece, and a second process performed from a second surface of the semiconductor layer stack, e.g., after flipping the workpiece.

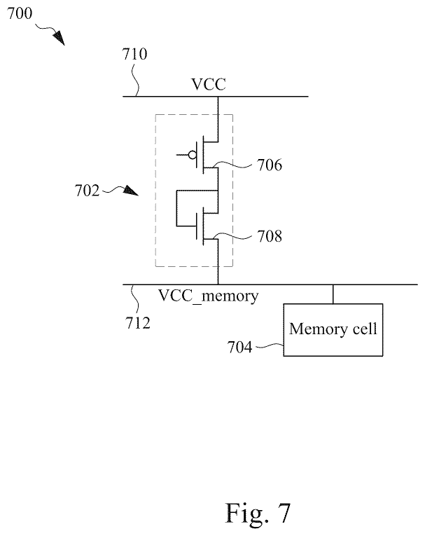

FIG. 7 is a schematic diagram of an integrated circuit (IC) 700 including a stacked PIN diode in accordance with some embodiments. The IC 700 includes a header switch 702 connected to a memory cell 704. One of ordinary skill in the art would understand that this description is not limited to utilizing a stacked PIN diode in a header switch 702 and that other implementations of the stacked PIN diode in IC devices are within the scope of this description. Other implementations of the stacked PIN diode of this description include vertical bi-polar transistors (BJTs) or other passive devices.

The header switch 702 is electrically between a power line 710 and a memory power line 712, in accordance with some embodiments. In some embodiments, the power line 710 is maintained at an upper power supply voltage VCC, and the memory power line 712 (which functions as a virtual power line) is connected to one or more memory cells 704. The header switch 702, as controlled with a power control signal PG, is either in a conducting state or in a non-conducting state. When the header switch 702 is in a conducting state, the memory power line 712 is connected to the power line 710, and consequently the upper power supply voltage VCC on the power line 710 is applied to the memory cell 704. When the header switch 702 is in a non-conducting state, the power connection between the memory power line 712 and the power line 710 is cut off, and consequently the upper power supply voltage VCC on the power line 710 is prevented from being applied to the memory cell 704. The header switch 702 provides a power management scheme which enables the memory cell 704 to receive the power based on an as-needed basis.

The header switch 702 includes a CFET transistor 706 and a stacked PIN diode 708. In some embodiments, the CFET transistor 706 is a p-type CFET transistor. The source terminal of the CFET transistor 706 is connected to the power line 710. The first terminal of the stacked PIN diode 708 is connected to the memory power line 712. The drain terminal of the CFET transistor 706 is connected to a second terminal of the stacked PIN diode 708. The gate terminal of the CFET transistor 706 is configured to receive the power control signal PG. When the power control signal PG is at a logic LOW voltage level, the header switch 702 is set to the conducting state. When the power control signal PG is at a logic HIGH voltage level, the header switch 702 is set to the non-conducting state.

An aspect of this description relates to a diode structure. The diode structure includes a first stack of semiconductor layers, wherein the first stack of semiconductor layers includes a plurality of first semiconductor layers arranged in an alternating arrangement with a plurality of second semiconductor layers, and each of the plurality of first semiconductor layers has a different composition from each of the plurality of second semiconductor layers. The diode structure further includes a second stack of semiconductor layers, wherein the second stack of semiconductor layers includes a plurality of third semiconductor layers arranged in an alternating arrangement with a plurality of fourth semiconductor layers, and each of the plurality of third semiconductor layers has a different composition from each of the plurality of fourth semiconductor layers. The diode structure further includes a fifth semiconductor layer between the first stack of semiconductor layers and the second stack of semiconductor layers, wherein a composition of the fifth semiconductor layer is different from each of the plurality of first semiconductor layers, each of the plurality of second semiconductor layers, each of the plurality of third semiconductor layers and each of the plurality of fourth semiconductor layers. The diode structure further includes an n-type doped region in the first stack of semiconductor layers. The diode structure further includes a p-type doped region in the second stack of semiconductor layers. In some embodiments, each of the plurality of first semiconductor layers has a same composition as each of the plurality of third semiconductor layers. In some embodiments, each of the plurality of second semiconductor layers has a same composition as each of the plurality of fourth semiconductor layers. In some embodiments, each of the plurality of first semiconductor layers and each of the plurality of third semiconductor layers comprises silicon. In some embodiments, each of the plurality of second semiconductor layers and each of the plurality of fourth semiconductor layers comprises silicon germanium, and a germanium concentration of each of the plurality of second semiconductor layers is higher than a germanium concentration of each of the plurality of first semiconductor layers. In some embodiments, the fifth semiconductor layer comprises silicon germanium, and a germanium concentration of the fifth semiconductor layer is greater than the germanium concentration of each of the plurality of second semiconductor layers. In some embodiments, the n-type doped region is vertically aligned with the p-type doped region.

An aspect of this description relates to a semiconductor device. The semiconductor device includes a complementary field effect transistor (CFET) device. The semiconductor device further includes a stacked PIN diode connected to the CFET device. The stacked PIN diode includes a first stack of semiconductor layers, wherein the first stack of semiconductor layers includes alternating layers having a first composition and a second composition, and the first composition is different from the second composition. The stacked PIN diode further includes a second stack of semiconductor layers, wherein the second stack of semiconductor layers includes alternating layers having the first composition and the second composition. The stacked PIN diode further includes an intervening semiconductor layer between the first stack of semiconductor layers and the second stack of semiconductor layers, wherein a composition of the intervening semiconductor layer is different from the first composition and the second composition. The stacked PIN diode further includes a plurality of n-type doped regions in the first stack of semiconductor layers. The stacked PIN diode further includes a plurality of p-type doped regions in the second stack of semiconductor layers. In some embodiments, each of the plurality of the n-type doped regions is vertically aligned with a corresponding p-type doped region of the plurality of p-type doped regions. In some embodiments, the CFET device includes a first plurality of channel layers; a second plurality of channel layers; and an isolation layer between the first plurality of channel layers and the second plurality of channel layers. In some embodiments, the intervening semiconductor layer is horizontally aligned with the isolation layer. In some embodiments, a number of the first plurality of channel layers is equal to a number of layers having the first composition in the first stack of semiconductor layers. In some embodiments, the first composition comprises silicon, the second composition comprises silicon germanium, and a germanium concentration of the second composition is greater than a germanium concentration of the first composition. In some embodiments, the first composition is free of germanium. In some embodiments, a germanium concentration of the first composition is greater than a germanium concentration of the second composition. In some embodiments, the CFET device is electrically connected in parallel with the stacked PIN diode. In some embodiments, the stacked PIN diode further includes a dummy gate structure along a surface of the first stack of semiconductor layers, wherein dummy gate structure comprises a first gate spacer. In some embodiments, the CFET device further includes a gate structure, wherein the gate structure comprises a second gate spacer. In some embodiments, a top-most surface of the first gate spacer is co-planar with a top-most surface of the second gate spacer.

An aspect of this description relates to a method of making a diode structure. The method includes forming a semiconductor layer stack, wherein the semiconductor layer stack includes alternating layers having different compositions, and a central semiconductor layer of the semiconductor layer stack has a different composition than all other layers in the semiconductor layer stack. The method further includes forming a first implantation mask on a first surface of the semiconductor layer stack. The method further includes implanting, using the first implantation mask, dopant of a first dopant type into the first surface of the semiconductor layer stack. The method further includes forming a second implantation mask on a second surface of the semiconductor layer stack, wherein the second implantation mask is vertically aligned with the first implantation mask. The method further includes implanting, using the second implantation mask, dopants of a second dopant type into the second surface of the semiconductor layer stack, wherein the second dopant type is opposite the first dopant type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A diode structure comprising:
a first stack of semiconductor layers, wherein the first stack of semiconductor layers comprises a plurality of first semiconductor layers arranged in an alternating arrangement with a plurality of second semiconductor layers, and each of the plurality of first semiconductor layers has a different composition from each of the plurality of second semiconductor layers;
a second stack of semiconductor layers, wherein the second stack of semiconductor layers comprises a plurality of third semiconductor layers arranged in an alternating arrangement with a plurality of fourth semiconductor layers, and each of the plurality of third semiconductor layers has a different composition from each of the plurality of fourth semiconductor layers;
a fifth semiconductor layer between the first stack of semiconductor layers and the second stack of semiconductor layers, wherein a composition of the fifth semiconductor layer is different from each of the plurality of first semiconductor layers, each of the plurality of second semiconductor layers, each of the plurality of third semiconductor layers and each of the plurality of fourth semiconductor layers;
an n-type doped region in the first stack of semiconductor layers; and
a p-type doped region in the second stack of semiconductor layers.

2. The diode structure of claim 1, wherein each of the plurality of first semiconductor layers has a same composition as each of the plurality of third semiconductor layers. P20241256US01

3. The diode structure of claim 1, wherein each of the plurality of second semiconductor layers has a same composition as each of the plurality of fourth semiconductor layers.

4. The diode structure of claim 1, wherein each of the plurality of first semiconductor layers and each of the plurality of third semiconductor layers comprises silicon.

5. The diode structure of claim 4, wherein each of the plurality of second semiconductor layers and each of the plurality of fourth semiconductor layers comprises silicon germanium, and a germanium concentration of each of the plurality of second semiconductor layers is higher than a germanium concentration of each of the plurality of first semiconductor layers.

6. The diode structure of claim 5, wherein the fifth semiconductor layer comprises silicon germanium, and a germanium concentration of the fifth semiconductor layer is greater than the germanium concentration of each of the plurality of second semiconductor layers.

7. The diode structure of claim 1, wherein the n-type doped region is vertically aligned with the p-type doped region.

8. A semiconductor device comprising:
a complementary field effect transistor (CFET) device; and
a stacked PIN diode connected to the CFET device, wherein the stacked PIN diode comprises:
a first stack of semiconductor layers, wherein the first stack of semiconductor layers comprises alternating layers having a first composition and a second composition, and the first composition is different from the second composition;
a second stack of semiconductor layers, wherein the second stack of semiconductor layers comprises alternating layers having the first composition and the second composition;
an intervening semiconductor layer between the first stack of semiconductor layers and the second stack of semiconductor layers, wherein a composition of the intervening semiconductor layer is different from the first composition and the second composition;
a plurality of n-type doped regions in the first stack of semiconductor layers; and
a plurality of p-type doped regions in the second stack of semiconductor layers.

9. The semiconductor device of claim 8, wherein each of the plurality of the n-type doped regions is vertically aligned with a corresponding p-type doped region of the plurality of p-type doped regions.

10. The semiconductor device of claim 8, wherein the CFET device comprises:
a first plurality of channel layers;
a second plurality of channel layers; and
an isolation layer between the first plurality of channel layers and the second plurality of channel layers.

11. The semiconductor device of claim 10, wherein the intervening semiconductor layer is horizontally aligned with the isolation layer.

12. The semiconductor device of claim 10, wherein a number of the first plurality of channel layers is equal to a number of layers having the first composition in the first stack of semiconductor layers.

13. The semiconductor device of claim 8, wherein the first composition comprises silicon, the second composition comprises silicon germanium, and a germanium concentration of the second composition is greater than a germanium concentration of the first composition.

14. The semiconductor device of claim 13, wherein the first composition is free of germanium.

15. The semiconductor device of claim 13, wherein a germanium concentration of the first composition is greater than a germanium concentration of the second composition.

16. The semiconductor device of claim 8, wherein the CFET device is electrically connected in parallel with the stacked PIN diode.

17. The semiconductor device of claim 8, wherein the stacked PIN diode further comprises:
a dummy gate structure along a surface of the first stack of semiconductor layers, wherein dummy gate structure comprises a first gate spacer.

18. The semiconductor device of claim 17, wherein the CFET device further comprises:
a gate structure, wherein the gate structure comprises a second gate spacer.

19. The semiconductor device of claim 18, wherein a top-most surface of the first gate spacer is co-planar with a top-most surface of the second gate spacer.

20. A method of making a diode structure, the method comprising:
forming a semiconductor layer stack, wherein the semiconductor layer stack comprises alternating layers having different compositions, and a central semiconductor layer of the semiconductor layer stack has a different composition than all other layers in the semiconductor layer stack;
forming a first implantation mask on a first surface of the semiconductor layer stack;
implanting, using the first implantation mask, dopant of a first dopant type into the first surface of the semiconductor layer stack;
forming a second implantation mask on a second surface of the semiconductor layer stack, wherein the second implantation mask is vertically aligned with the first implantation mask; and
implanting, using the second implantation mask, dopants of a second dopant type into the second surface of the semiconductor layer stack, wherein the second dopant type is opposite the first dopant type.
